(19) United States
(12) Patent Application Publication
(10) Pub. No.: US 2012/0052679 A1
(43) Pub. Date: Mar. 1, 2012

(54) Method of Fabricating an Ohmic contact to n-type Gallium Nitride

(76) Inventors: Wenting Hou, Troy, NY (US); Theeradetch Detchprohm, Niskayuna, NY (US); Christian Martin Wetzel, Troy, NY (US)

(21) Appl. No.: 13/222,800

(22) Filed: Aug. 31, 2011

Related U.S. Application Data
(60) Provisional application No. 61/378,676, filed on Aug. 31, 2010.

(51) Int. Cl. H01L 21/28

(52) U.S. Cl. 438/660; 257/E21.158

(57) ABSTRACT

A method of providing a metal contact to n-type Gallium Nitride is disclosed. The method does not require high temperatures that often lead to a degradation of semiconductor materials, dielectric films, interfaces and/or metal-semiconductor junctions. The method can be applied at practically any step of a semiconductor device fabrication process and results in high quality ohmic contact with low contact resistance and high current handling capability. Present invention significantly simplifies the fabrication process of semiconductor devices, such as Gallium Nitride-based Light Emitting Diodes and Laser Diodes, while improving the resulting performance of the said devices. The invention can also be applied to improve the performance of electronic devices based on Gallium Nitride material system, especially where an additional annealing step is beneficial during the fabrication process.

### CROSS-REFERENCE TO RELATED APPLICATION

This application claims the benefit of Provisional Patent Application Ser. No. 61/378,676, filed on Aug. 31, 2010 by present inventors.

### FEDERALLY SPONSORED RESEARCH

Not Applicable

### SEQUENCE LISTING OR PROGRAM

Not Applicable

### FIELD OF THE DISCLOSURE

The present invention is related to semiconductor device fabrication. More particularly, present invention teaches a method of fabricating high quality metal contacts to n-type Gallium Nitride which does not involve steps that could degrade other elements of a semiconductor device.

### BACKGROUND OF THE DISCLOSURE

The useful function of electronic and especially optoelectronic devices is achieved by passing through them the electric current. In most cases, the electric current is applied through a set of metal contacts. The said contacts develop a voltage drop across them in response to the passing current, resulting in the electric power dissipation which is parasitic with respect to the useful function of the said device. The problem of contact quality is, therefore, important in optimizing the energy efficiency of any electronic and optoelectronic device.

The process of obtaining a high quality, low voltage drop contact to a semiconductor material involves several steps including, but not limited to semiconductor material surface cleaning and preparation, contact material (usually metal, sequence of metals or other conducting material) deposition, and following anneal at specified temperature and in specified ambient. Every fabrication step is usually optimized for the purpose of obtaining a contact with desired properties.

Since the process of fabrication of a semiconductor device involves many steps and usually more than just one type of the metal contacts, it is important that every step of the contact formation is compatible with the overall process flow, and the resulting contact be stable over all fabrication steps performed after its formation.

In particular, the fabrication process of Gallium Nitride-based light emitting semiconductor devices involves the formation of two types of metal contacts, namely the contacts to the n-type Gallium Nitride (n-contact) and to the p-type Gallium Nitride (p-contact). The standard fabrication process of the n-contact requires the anneal step at quite high temperature, between 650 and 900 degrees of Celsius scale, in the ambient of air or nitrogen gas. This, however, may degrade the quality of the p-contact in case it is formed prior to the anneal of the n-contact. In turn, the formation of the p-contact involves the anneal at somewhat lower temperature, from 400 to 550 degrees of Celsius scale, but in oxygen gas ambient. This is known to result in degradation of the quality of the n-contact, in case it is formed prior to the p-contact. Thus, a development of a compatible process flow resulting in the formation of both types of contacts of high quality is a challenging task.

In a particular case of Gallium Nitride optoelectronic devices, several solutions were previously suggested to overcome the problem indicated above. The solutions include using different contact materials or material stacks, and/or using advanced semiconductor surface preparation procedures. With respect to this last possibility, it was previously suggested that the surface of the n-type Gallium Nitride could be oxygen plasma pre-treated in order to improve the quality of the n-contact (See for example, U.S. Pat. No. 6,423,562 by Masaaki Nido and Yukihiro Hisanaga). However, this treatment represents an additional technological step in the semiconductor device fabrication and may lead to the degradation of the surfaces of a semiconductor die other than the portion of the surface intentionally treated, for example, a surface of p-type Gallium Nitride.

Yet another prior art U.S. Pat. No. 7,214,325 by J. L. Lee, H. W. Jang, J. K. Kim and C. Jeon describes the room temperature ohmic contact to n-type Gallium Nitride obtained by metal deposition onto the semiconductor surface immediately after the Inductively Coupled Plasma treatment. Our studies, however, do not confirm the feasibility of this method. It will be shown below that the contact obtained by the method of Lee's invention results in a non-linear contact with a high voltage drop while passing the current.

High temperature annealing is not always necessary if very high doping levels in the n-type Gallium Nitride are used (see for example, a paper by J. D. Guo, C. I. Lin, M. S. Feng, F. M. Pan, G. C. Chi and C. T. Lee, “A bilayer Ti/Ag ohmic contact for highly doped n-type GaN films”, in Applied Physics Letters, Vol. 68, No. 2, pages 235-237, 8 Jan. 1996). Such high doping levels, however, interfere with the epitaxial material quality and may not be achieved in real device structures.

The present invention relates to the contact fabrication optimization and contact quality improvement to the n-type Gallium Nitride material. The invention teaches the fabrication steps to form an n-contact which is fully compatible with the conventional fabrication flow of Gallium Nitride-based electronic and optoelectronic devices and provides a better quality contact, reducing parasitic power dissipation during the device operation.

### SUMMARY OF THE INVENTION

The present invention provides an improvement to the metal contact fabrication process to the Gallium Nitride material of the n-type of conductivity. In one preferred embodiment, the present invention teaches the method that allows combining the p-contact post-treatment and n-type Gallium Nitride surface pre-treatment in one convenient fabrication step. This is made possible by adjusting the fabrication flow in such a way that the mesa structure formation and the p-metal deposition are performed prior to the n-contact formation. The new method allows producing robust, high-quality low-resistance contacts to n-type Gallium Nitride without affecting the quality of earlier formed p-contacts.

### BRIEF DESCRIPTION OF THE DRAWINGS

These and other advantages of the present invention will be more readily understood from the following discussion taken in conjunction with the accompanying drawings, among which:

FIG. 1 is a diagram illustrating the conventional method of producing a contact to n-type Gallium Nitride within the processing flow of a Light Emitting Diode;

FIG. 2 is a diagram illustrating yet another conventional method of producing a contact to n-type Gallium Nitride within the processing flow of a Light Emitting Diode;

FIG. 3 is a diagram illustrating the method of producing a contact to n-type Gallium Nitride provided by the present invention, taken for exemplary purposes in conjunction and within the processing flow of a Light Emitting Diode. The n-metal anneal is not necessary for ohmic contact formation;

FIG. 4 is a diagram illustrating the method of producing a contact to n-type Gallium Nitride provided by the present invention, concluded with optional n-metal anneal that can further improve the quality of the n-contact, taken for exemplary purposes in conjunction and within the processing flow of a Light Emitting Diode;

FIG. 5 is a plot of current-voltage characteristics demonstrating the quality of the contact obtained by the method of the present invention. The size of the metal contacts is 140 μm×100 μm, with a space of 5 μm between the two contacts.

FIG. 6 provides the current-voltage characteristics comparison of the contact obtained by the method of the present invention followed by thermal treatment to the conventional contact subject to similar thermal treatment. The size of the metal contacts is 140 μm×100 μm, with a space of 5 μm between the two contacts.

### DETAILED DESCRIPTION OF THE INVENTION

It is understood for the purpose of the following description and examples that the discussion based on the Light Emitting Diode fabrication is exemplary only and can be extended on any other semiconductor device which comprises an n-type Gallium Nitride layer and at least one metal contact to it. It is further understood that the findings of the present invention are readily applicable to other nitride based materials and compounds; therefore, for the purpose of the present invention, we use cumulative term “Gallium Nitride” to cover the family of materials comprising Boron Nitride BN, Aluminum Nitride AlN, Gallium Nitride GaN, Indium Nitride InN and their compounds.

It is also understood that for the purpose of the preceding discussion and following description of the present invention, the term “metal contact” is used to describe any type of the electrical contact to the semiconductor material, and is preferably referred to an ohmic type of electrical contact. It can be, however, discovered by a skilled artisan that in some cases, without changing the scope of the present invention, the term “metal contact” can refer to a contact that does not necessarily by fact contain metal or an alloy of metals, such as, for example, conventional oxide-based transparent contact containing Indium Tin Oxide (ITO) and its existing or further discovered modifications.

Referring further to the fabrication process of a Light Emitting Diode, we refer to the metal contact to the p-type material (usually top layer) as to the p-contact; respectively, we refer to the metal contact to the n-type material (usually buried) as to the n-contact.

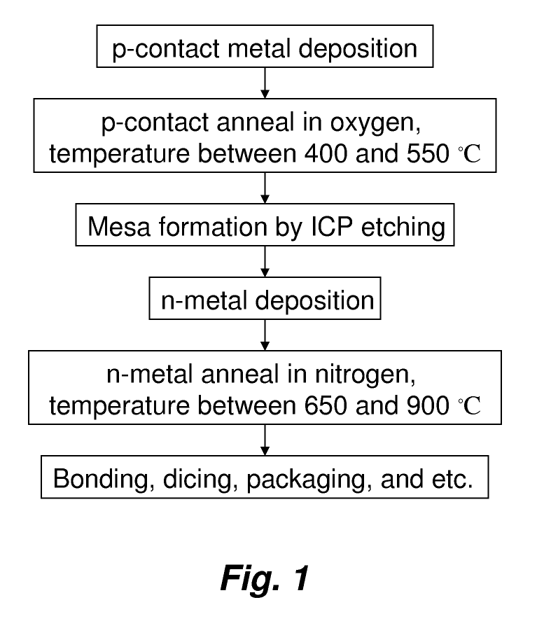

The standard processing sequence of a conventional Light Emitting Diode comprises the p-contact fabrication, followed by mesa structure formation and n-contact fabrication. This sequence is presented by the diagram of FIG. 1. Following the p-contact metal stack deposition, an oxidizing anneal is performed to improve the contact resistance. This anneal is performed at relatively low (400 to 550 degrees Celsius) temperature.

The mesa structure is obtained by selective combined Inductively Coupled Plasma (ICP) and Reactive Ion Etching (RIE) technique using either separate photoresist-based masking of the active device area, or utilizing the protective property of the p-contact metal. Finally, the n-metal stack patterns are deposited surrounding the active area of the devices. We found that, in spite of the data delivered in U.S. Pat. No. 7,214,325 by J. L. Lee et al., the n-contact as deposited on the ICP-etched n-GaN surface does not provide good contact quality and/or linearity. It is thought that the GaN surface is extremely sensitive to particular ambient conditions that cannot be accurately controlled during the ICP etching or between the ICP etching and the metal deposition.

In order to improve the quality of the n-contact, an annealing step in Nitrogen ambient is needed at a relatively high (650 to 900 degrees Celsius) temperature. Unfortunately, such high temperature annealing results in clusterizationand degradation of the p-metal, if it was deposited as a prior step in the process sequence being discussed. Therefore, the standard processing sequence, as depicted by FIG. 1, does not allow for contact resistance optimization for both, n-contact and p-contact.

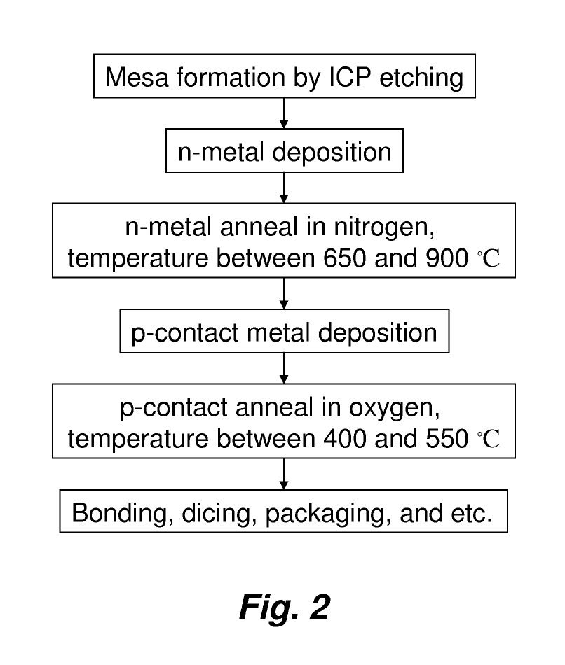

FIG. 2 presents the diagram of yet another conventionally used process flow of GaN-based Light Emitting Diodes. According to this process sequence, the mesa structure formation using ICP etching and n-contact metal stack deposition are performed prior to the p-contact formation, and followed by the n-contact anneal, necessary for the reason discussed above. The process is then concluded with the deposition of the p-contact metal stack over the appropriate portions of the semiconductor surface and another anneal at relatively low temperature, 400 to 550 degrees Celsius, in ambient comprising Oxygen. The said Oxygen-comprising ambient is commonly known to any artisan skilled in the art to be a key process feature to obtain low contact resistance and good current spreading of the p-contact metal layer, preserving at the same time some level of transparency for the light being generated by the device. This step, on the other hand, leads to a significant degradation of the n-contact quality. In particular, it results in a nearly twofold increase of the contact resistance of the said n-contact. Thus, existing standard process flows that are based on consecutive formation of the contacts to n- and p-layers of the device result in the degradation of the primarily formed contact while fabricating the latter one.

It is known that the presence of Oxygen atoms at the GaN surface assists the formation of an ohmic contact to the said surface. Two mechanisms are believed to be responsible for the effect. First, Oxygen is known as a donor-type dopant to GaN and related compounds; it is known that higher doping of the regions adjacent to the semiconductor surfaces in general results in lower contact resistances. In addition, Oxygen typically creates stronger bonds with Gallium than Nitrogen and it substitutes for the Nitride family compounds, so that the presence of Oxygen atoms at the semiconductor surface results in a certain level of Nitrogen release and Nitrogen vacancy creation, which, like a donor-type dopant, also act as a donor of electrons.

The present invention utilizes the advantage of the Oxygen treatment for the n-contact formation as described above. It is discovered that the thermal treatment of the ICP-etched surface of n-type GaN material in Oxygen ambient performed at relatively low (400 to 550 degrees Celsius) temperature assists the formation of a metal contact to the said GaN material for the n-contact metal stack as deposited, without a need for further treatment. It becomes possible, therefore, to combine in one fabrication step both, the annealing of the p-contact and the surface pre-treatment of the n-type Gallium Nitride.

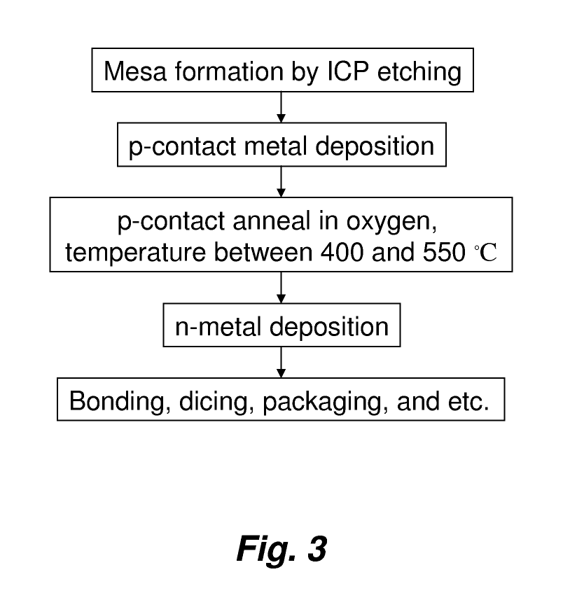

An exemplary process flow benefiting from the teaching of the present invention is illustrated by the diagram of FIG. 3 of the attached drawings. It will be appreciated by any skilled artisan that the process flow as illustrated by FIG. 3 is substantially simplified as compared to the conventional process flows such as laid out in FIGS. 1 and 2.

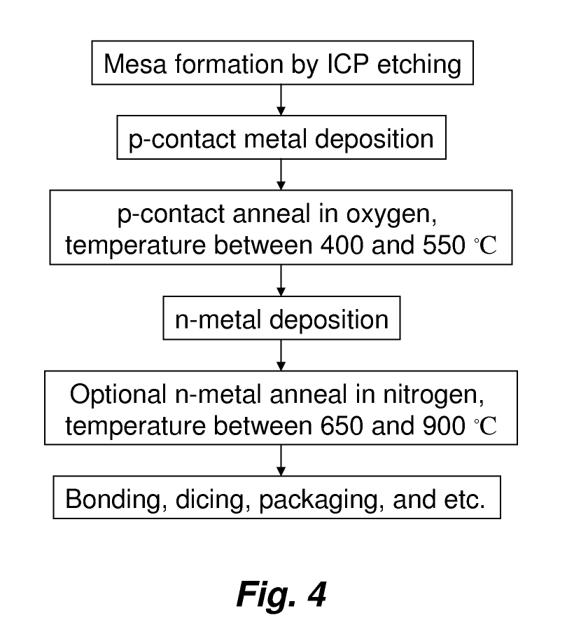

Although the major advantage of the metal contact fabricated in accordance with the present invention is the absence of the necessity for the contact anneal, an artisan skilled in the art may find it advantageous not to withdraw the annealing step from the fabrication sequence. In the variation to the process flow of FIG. 3, again taken for exemplary purposes within the fabrication process of a conventional LED, as illustrated by FIG. 4, the contact fabricated in accordance with the teachings of present invention is further annealed in Nitrogen ambient, preferrably in the temperature range between 650 and 900 degrees Celsius. Therefore, in case for example, when the degradation of the p-contact during such anneal does not significantly affect the device performance, the annealing step may be still performed to further improve the n-contact resistance, mechanical strength and adhesion, and/or other important properties discovered by skilled artisan.

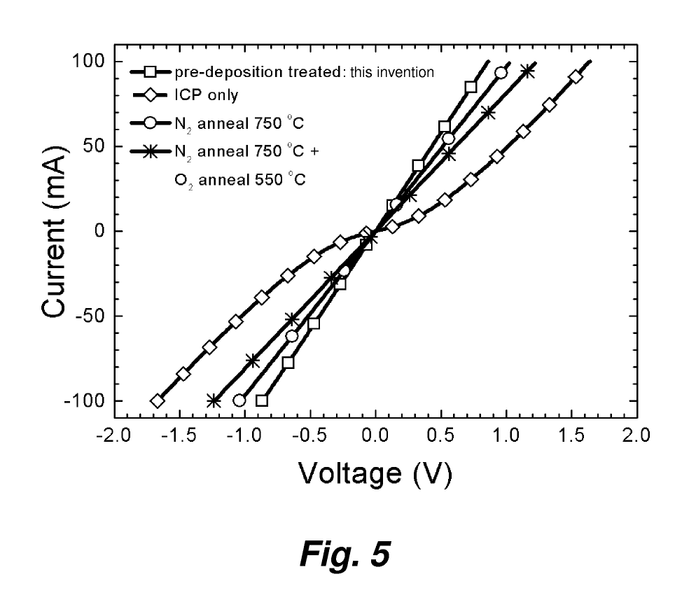

The current-voltage (I-V) characteristics of the n-contacts obtained with the use of the process flows described above with respect to corresponding diagrams in FIGS. 1 through 3 are shown in FIG. 5. The current-voltage characteristic as in the present invention is given by the open squares. The data for the n-contact as deposited on the ICP-pretreated n-GaN surface is given by open diamonds. The open circles correspond to the n-contact formed by the process flow as described by the diagram of FIG. 1. The stars denote the n-contact formed by the process flow as described by the diagram of FIG. 2. From FIG. 5, the contact prepared in accordance with the teaching of the present invention demonstrates that at any current level there is less voltage drop among the compared contacts.

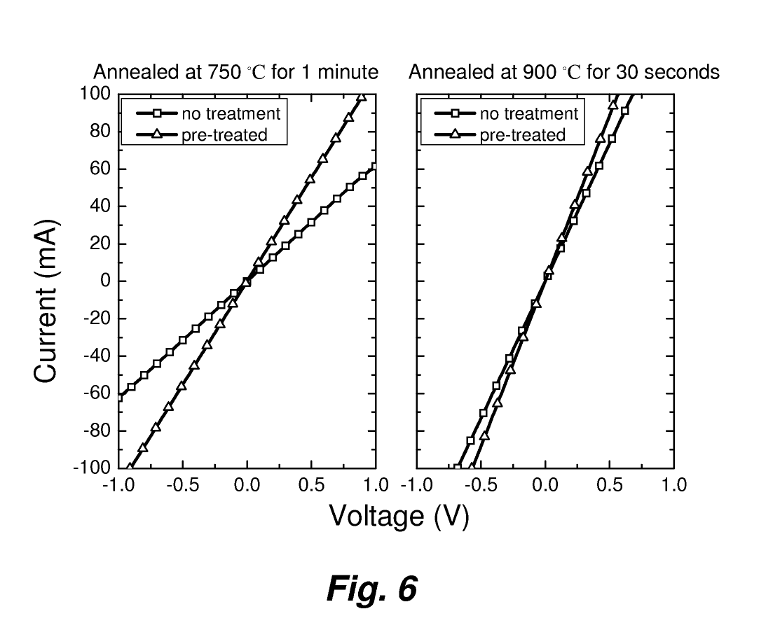

In an additional embodiment of the present invention, the method discussed herein is advantageous to use even in cases where only the n-type contacts are needed for device operation. We found that the method of thermal pre-treatment in oxygen is equally applicable to the etched and as-grown n-type Gallium Nitride. Also, referring to the data presented in FIG. 6, the contact pre-treated in accordance with the present invention and subjected to further post-metallization anneal outperforms similarly annealed contact without pre-treatment.

In light of the above discussion, one of the advantages of the present invention is improved quality of the electric contact to n-type Gallium Nitride or related material/compound. Yet another advantage is substantial simplification of the semiconductor device fabrication process, in the form of reduction of fabrication steps, made possible with the help of the teachings of the present invention.

What is claimed is:

1. A method of forming a contact on a Gallium Nitride layer, a method comprising:
obtaining a semiconductor structure comprising a layer of n-type Gallium Nitride or related material/compound,
obtaining a surface of a said n-type Gallium Nitride or related material/compound,
performing thermal treatment of the said surface at the temperatures preferably in the range 400-550 degrees of the Celsius scale in the presence of Oxygen gas,
forming a metal contact on the said surface, wherein the metal contact forms an ohmic contact with the said layer of Gallium Nitride or related material/compound.

2. A method of forming a contact on n-type Gallium Nitride layer, a method of claim 1 followed by thermal anneal at temperatures ranging from 650 to 900 degrees of the Celsius scale in the presence of Nitrogen gas.
